(19) United States
(12) Patent Application Publication
(10) Pub. No.: US 2026/0096263 A1
(43) Pub. Date: Apr. 2, 2026

(54) LIGHT EMITTING DIODE (LED) DISPLAY DEVICE

(71) Applicant: LG DISPLAY CO., LTD., SEOUL (KR)

(72) Inventors: TaeYoon Kim, Seoul (KR); HyeSun Jung, Seoul (KR); BungGoo Kim, Paju-si (KR); HyoungHo Ahn, Paju-si (KR); HeeWon Lee, Paju-si (KR); JunYoung Jo, Paju-si (KR)

(21) Appl. No.: 19/334,434

(22) Filed: Sep. 19, 2025

(30) Foreign Application Priority Data
Sep. 30, 2024 (KR) 10-2024-0132453

(51) Int. Cl. H10H 29/41; H10H 29/37; H10H 29/80; H10H 29/855

(52) U.S. Cl. CPC H10H 29/41; H10H 29/37; H10H 29/842; H10H 29/8552; H10H 29/882

(57) ABSTRACT

A display device includes a substrate including an active area, a non-active area disposed on at least one side surface of the active area, and a bending area disposed between the active area and the non-active area, a plurality of insulating layers disposed on the substrate, a bank disposed on the plurality of insulating layers, at least one micro light emitting diode (LED) disposed on the bank, an optical layer disposed on the plurality of insulating layers, a dam area between the active area and the bending area and a first dam disposed in the dam area, wherein the first dam includes a first dam layer which is formed of the same material as the bank.

### CROSS-REFERENCE TO RELATED APPLICATIONS

Pursuant to 35 U.S.C. § 119(a), this application claims the benefits of an earlier filing date and right of priority to Korean Patent Application No. 10-2024-0132453 filed on Sep. 30, 2024, in the Korean Intellectual Property Office, the entire disclosure of which is incorporated herein by reference.

### TECHNICAL FIELD

The present disclosure relates to an LED display device.

### BACKGROUND

Recently, as display devices become larger, the demand for flat display elements that occupy a less space is increasing. The technology of flat panel display devices, such as liquid crystal display (LCD) devices or organic electroluminescent display (OLED) devices including organic light emitting diodes (OLED) is rapidly advancing.

Recently, in order to overcome the problems of the LCD device and/or the OLED device as described above, an LED display device which uses a light emitting diode as a light emitting element is proposed. For an LED display device, a small-sized LED, such as a mini-LED, or an ultra-small-sized LED, such as a micro-LED, can be used.

Such an LED display device is a display device in which a mini or micro unit of ultra small-sized LED is disposed in each sub pixel to implement images and has great advantages in terms of low power consumption and reduction in size.

### SUMMARY

According to an implementation of the present disclosure, a display device includes a substrate including an active area, a non-active area disposed on at least one side surface of the active area, and a bending area disposed between the active area and the non-active area, a plurality of insulating layers disposed on the substrate, a bank disposed on the plurality of insulating layers, at least one micro LED disposed on the bank, an optical layer disposed on the plurality of insulating layers, a dam area between the active area and the bending area and a first dam disposed in the dam area, wherein the first dam includes a first dam layer which is formed of the same material as the bank.

According to another implementation of the present disclosure, a display device includes a substrate including an active area, a non-active area disposed on at least one side surface of the active area, and a bending area between the active area and the non-active area, a plurality of insulating layers disposed on the substrate in the active area, a bank disposed on the plurality of insulating layers, at least one micro LED disposed on the bank, an optical layer disposed on the plurality of insulating layers, a black matrix disposed on the optical layer and at least one dam disposed in a dam area between the active area and the bending area, wherein at least one dam includes a first dam layer which is formed of the same material as the bank.

Other detailed matters of the example implementations are included in the detailed description and the drawings.

According to the present disclosure, the structural change characteristic of the upper layers due to the step and the thickness change of the end portion of the lower insulating film in the non-active area of the LED display device may be improved.

According to the present disclosure, thicknesses of upper layers involved in the light emission efficiency may be uniformized.

Accordingly, the light is uniformly emitted from the LED in a center portion and an outer peripheral portion of the active area.

The effects according to the present disclosure are not limited to the contents exemplified above, and more various effects are included in the present specification.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with implementations of the disclosure.

It is to be understood that both the foregoing general description and the following detailed description are example and explanatory and are intended to provide further explanation of the inventive concepts as claimed.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exploded perspective view of an example of a display device according to an implementation of the present disclosure;

FIG. 2 is a plan view of an example of a display device according to an implementation of the present disclosure;

FIG. 3 is a plan view an example of enlarging an area 3 of FIG. 2 according to an implementation of the present disclosure;

FIG. 4 is a plan view an example of enlarging an area 4 of FIG. 2 according to an implementation of the present disclosure;

FIG. 5 is a plan view of an example of a display device according to an implementation of the present disclosure;

FIG. 6 is an enlarged view of an example of a light emitting diode according to an implementation of the present disclosure;

FIG. 7 is an example of a cross-sectional view taken along A-A′ of FIG. 3 according to an implementation of the present disclosure;

FIG. 8 is an example of a cross-sectional view taken along A-A′ of FIG. 3 according to an implementation of the present disclosure;

FIG. 9 is an example of a cross-sectional view taken along B-B′ of FIG. 4 according to an implementation of the present disclosure;

FIG. 10 is an example of a cross-sectional view taken along C-C′ of FIG. 4 according to another implementation of the present disclosure; and

FIG. 11 is a plan view illustrating an example of a display device according to an implementation of the present disclosure.

### DETAILED DESCRIPTION

The present disclosure relates to an LED display device, and more particularly, for example, without limitation, an LED display device in which a thickness change of upper layers due to a step of end portions of insulating films in a bending area of a non-active area is improved.

In an LED display device, it can be important to planarize lower portions to place the LEDs. In order to planarize the lower portions, insulating layers formed of an organic material may be disposed.

In some scenarios, the end areas of the insulating layers in the non-active area of the LED display device are not flat, but gradually reduce in thicknesses, which may cause steps and thickness change. The step and thickness change of the end portion may cause the change in the thickness of the layers thereabove.

Therefore, it can be beneficial to suppress the thickness change of the upper layers due to the step and the thickness change of the insulating films.

Implementations of the present disclosure can provide improvements in process efficiency without using an additional process while suppressing the thickness change of upper layers due to the step and the thickness change of lower insulating films.

Objects of the present disclosure are not limited to the above-mentioned objects, and other objects, which are not mentioned above, can be clearly understood by those skilled in the art from the following descriptions.

Reference will now be made in detail to implementations of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted or may be briefly discussed. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and characteristics of the present disclosure and a method of achieving the advantages and characteristics will be clear by referring to example implementations described below in detail together with the accompanying drawings. However, the present disclosure is not limited to the example implementations disclosed herein but will be implemented in various forms. The example implementations are provided by way of example only so that those skilled in the art can fully understand the disclosures of the present disclosure and the scope of the present disclosure.

The shapes, sizes, ratios, angles, numbers, and the like illustrated in the accompanying drawings for describing the example implementations of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

Any implementation described herein as an “example” is not necessarily to be construed as preferred or advantageous over other implementations.

When the position relation between two parts is described using the terms such as “on”, “above”, “below”, and “next”, one or more parts may be positioned between the two parts unless the terms are used with the term “immediately” or “directly”.

When explaining temporal relationships, terms such as “after,” “following,” “subsequent to,” or “before,” etc., may include non-consecutive cases unless terms like “immediately” or “directly” are used.

Terms such as “first,” “second,” etc. are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) may be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component may be directly connected, coupled, joined, or attached to the other component, but unless explicitly specified otherwise, it may also be indirectly connected, coupled, joined, or attached with another component intervening between each component.

When a component or layer is described as being “in contact with” or “overlapping” another component or layer, the component or layer may directly contact or overlap the other component or layer, but unless explicitly specified otherwise, it should be understood that it may also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The terms “first direction”, “second direction”, “third direction”, “X-axis direction”, “Y-axis direction”, and “Z-axis direction” should not be interpreted solely as geometric relationships perpendicular to each other, but may indicate broader directionality within the range where the configuration of the present disclosure can function.

Unless otherwise defined, all terms (including technical and scientific terms) used herein have the same meaning as commonly understood by one of ordinary skill in the art to which example implementations belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these implementations may be provided so that this disclosure may be sufficiently thorough and complete to assist those skilled in the art to fully understand the scope of the present disclosure. Furthermore, the present disclosure is only defined by scopes of claims.

The features of various implementations in the present disclosure may be partially or wholly combined or associated with each other, various technical interlocking and operations are possible, and each implementation may be implemented independently of each other or may be implemented together in an associated relationship.

Hereinafter, a display device according to example implementations of the present disclosure will be described in detail with reference to accompanying drawings.

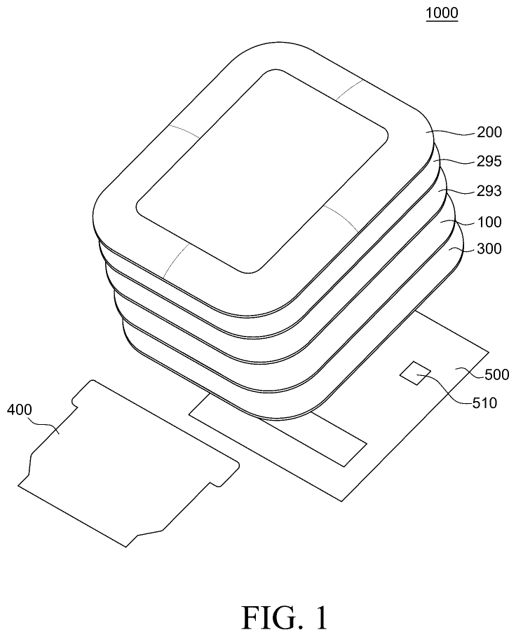

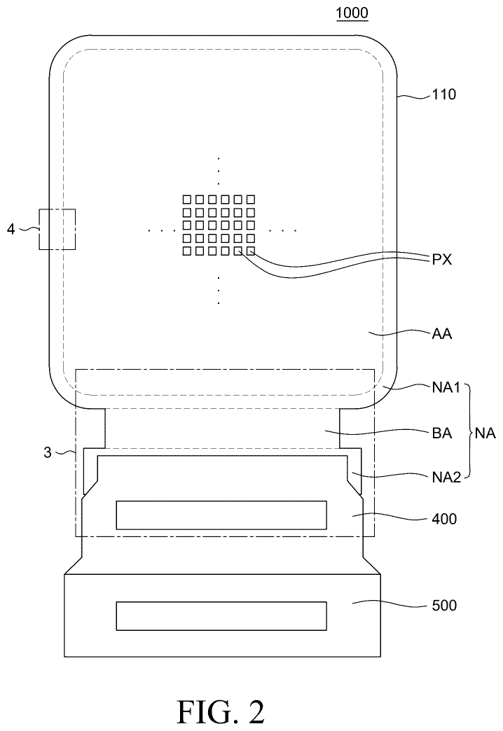

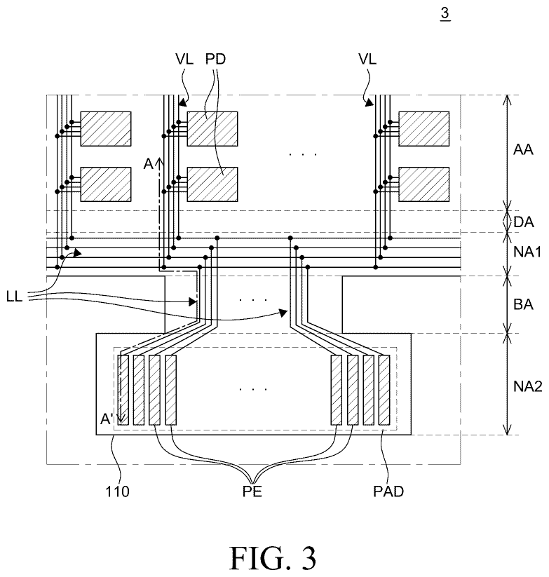

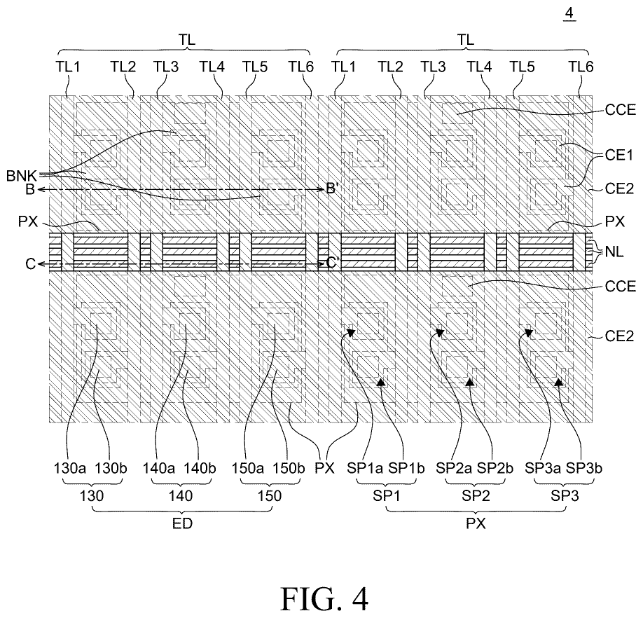

FIG. 1 is a perspective view illustrating a display device according to an example implementation of the present disclosure. FIG. 2 is a plan view of a display device according to an example implementation of the present disclosure. FIGS. 3 and 4 are enlarged views of a display device according to an example implementation of the present disclosure.

Referring to FIGS. 1 to 4, a display device 1000 according to an example implementation of the present disclosure includes a display panel 100, a polarization layer 293, an adhesive layer 295, a cover member 200, a support substrate 300, a flexible circuit board 400, and a printed circuit board 500. The cover member 200 is attached to the display panel 100 using the adhesive layer 295. The adhesive layer 295 is also disposed between the display panel 100 and the polarization layer 293 or between the display panel 100 and the support substrate 300.

The adhesive layer 295 may include an optically clear adhesive (OCA), an optically clear resin (OCR), or a pressure sensitive adhesive (PSA), but the example implementations of the present disclosure are not limited thereto.

For example, the display panel 100 of the display device 1000 includes a substrate 110. The substrate 110 may be a member which supports other components of the display device 1000. The substrate 110 is formed of an insulating material. For example, the substrate 110 may be formed of glass or resin. Further, the substrate 110 may also be formed of a material having a flexibility. For example, the substrate 110 may be formed of a plastic material having flexibility, such as polyimide (PI), but the example implementations of the present disclosure are not limited thereto.

The display panel 100 may implement information, videos, and/or images which are provided to users. For example, the display panel 100 includes an active area AA and a non-active area NA. For example, the substrate 110 includes an active area AA and a non-active area NA. However, the active area AA and the non-active area NA are not mentioned to be limited to the substrate 110, but may be mentioned for the entire display device 1000.

The active area AA is an area where images are displayed. The active area AA includes a plurality of pixels PX. Each of the plurality of pixels PX may be configured by a plurality of sub pixels. A plurality of micro LEDs is disposed in each of the plurality of sub pixels. The plurality of micro LEDs may be configured in different manners depending on the type of the display device 1000.

The non-active area NA is an area where no image is displayed. In the non-active area NA, various wiring lines and circuits for driving the plurality of pixels PX of the active area AA are disposed. For example, in the non-active area NA, various wiring lines and driving circuits are mounted and a pad unit PAD to which an integrated circuit and a printed circuit are connected is disposed, but the example implementations of the present disclosure are not limited thereto.

For example, the driving circuit may be a data driving circuit and/or a gate driving circuit, but the example implementations of the present disclosure are not limited thereto. Wiring lines through which a control signal for controlling driving circuits is supplied are disposed. For example, the control signal includes various timing signals including a clock signal, an input data enable signal, and synchronization signals, but the example implementations of the present disclosure are not limited thereto. The control signal is received through the pad unit PAD. For example, in the non-active area NA, link lines LL is disposed to transmit signals. For example, driving components, such as the flexible circuit board 400 and the printed circuit board 500, are connected to the pad unit PAD.

According to the present specification, the non-active area NA includes a first non-active area NA1, a bending area BA, and a second non-active area NA2. For example, the first non-active area NA1 is an area which encloses at least a part of the active area AA. The bending area BA is an area extending from at least one side, among a plurality of sides of the first non-active area NA1 and may be a bendable area. The second non-active area NA2 is an area extending from the bending area BA and the pad unit PAD is disposed therein. For example, the bending area BA is in a bent state and the other areas of the substrate 110 excluding the bending area BA may be in a flat state. In this case, as the bending area BA is bent, the second non-active area NA2 is located on a rear surface of the active area AA, but the example implementations of the present disclosure are not limited thereto.

The active area AA of the substrate 110 or the display device 1000 may be configured with various shapes depending on a design of the display device 1000. For example, the active area AA may be configured with a rectangular shape formed with four rounded corners, but the example implementations of the present disclosure are not limited thereto. As another example, the active area AA may be configured with a rectangular shape formed with four right-angled corners or a circular shape, but the example implementations of the present disclosure are not limited thereto.

According to the present disclosure, a width of the second non-active area NA2 in which the plurality of pad electrodes PE is disposed may be larger than a width of the bending area BA in which only a plurality of link lines LL is disposed. Further, a width of the active area AA in which the plurality of sub pixels is disposed is larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the example implementations of the present disclosure are not limited thereto.

Referring to FIG. 4, a plurality of pixel driving circuits PD is disposed in the active area AA. The plurality of pixel driving circuits PD may be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD includes a power line and a signal line for controlling emission on/off of the micro LED and/or an emission time. For example, the plurality of pixel driving circuits PD may be driving drives manufactured using a metal-oxide-silicon field effect transistor (MOSFET) manufacturing process on a semiconductor substrate, but the example implementations of the present disclosure are not limited thereto. The driving driver includes a plurality of pixel driving circuits PD and drives a plurality of sub pixels.

Referring to FIG. 1 together, the flexible circuit board 400 and the printed circuit board 500 may be disposed below the display panel 100. The flexible circuit board 400 and the printed circuit board 500 may be disposed at at least one edge of the display panel 100, but the example implementations of the present disclosure are not limited thereto.

A pad unit PAD including a plurality of pad electrodes PE is disposed in the second non-active area NA2. In the pad unit PAD, a driving component including one or more flexible circuit boards (or flexible films) 400 and the printed circuit board 500 may be attached or bonded. The plurality of pad electrodes PE of the pad unit PAD is electrically connected to one or more flexible circuit boards (or flexible films) 400 and transmits various signals (or powers) from the printed circuit board 500 and the flexible circuit board (or a flexible film) 400 to the plurality of pixel driving circuits PD of the active area AA.

The flexible circuit board (or flexible film) 400 may be a film on which various components are disposed on a base film having ductility. For example, driving ICs such as a gate driver IC or a data driver IC may be disposed in the flexible circuit board (or flexible film) 400, but the example implementations of the present disclosure are not limited thereto.

The printed circuit board 500 includes at least one hole 510, but the example implementations of the present disclosure are not limited thereto. An internal component which senses ambient light or temperature to be supplied to a plurality of sensors may be disposed in an area corresponding to at least one hole 510. For example, the internal component may include an ambient light sensor (ALS) or a temperature sensor, but the example implementations of the present disclosure are not limited thereto. For example, the hole 510 may be a transmission hole, but the example implementations of the present disclosure are not limited thereto.

Referring to FIGS. 1 to 3, the plurality of link lines LL is disposed in the non-active area NA. The plurality of link lines LL is wiring lines which transmit various signals from one or more flexible circuit boards (or flexible films) 400 and the printed circuit board 500 to the active area AA. The plurality of link lines LL extends from the plurality of pad electrodes PE of the second non-active area NA2 toward the bending area BA and the first non-active area NA1 to be electrically connected to the plurality of driving lines VL of the active area AA.

The plurality of driving lines VL is disposed in the active area AA to be electrically connected to each of the plurality of pixel driving circuits PD.

As the bending area BA is bent, a part of the plurality of link lines LL is bent together. A stress is concentrated in the bent part of the link line LL, which causes a crack on the link line LL. Accordingly, the plurality of link lines LL may be configured by a conductive material having excellent ductility to reduce the crack caused when the bending area BA is bent. For example, the plurality of link lines LL may be configured by a conductive material having excellent ductility, such as gold (Au), silver (Ag), or aluminum (Al), but the example implementations of the present disclosure are not limited thereto. Further, the plurality of link lines LL may be configured by one of various conductive materials used for the active area AA. For example, the plurality of link lines LL may be configured by molybdenum (Mo), chrome (Cr), titanium (Ti), nickel (Ni), neodymium (Nd), copper (Cu), and an alloy of silver (Ag) and magnesium (Mg) or an alloy thereof, but the example implementations of the present disclosure are not limited thereto. The plurality of link lines LL may be configured by a multi-layered structure including various conductive materials. For example, the plurality of link lines LL may be configured with a triple layered structure of titanium (Ti)/aluminum (Al)/titanium (Ti), but the example implementations of the present disclosure are not limited thereto.

FIGS. 4 to 10 are plan views and cross-sectional views of a display device according to an example implementation of the present disclosure.

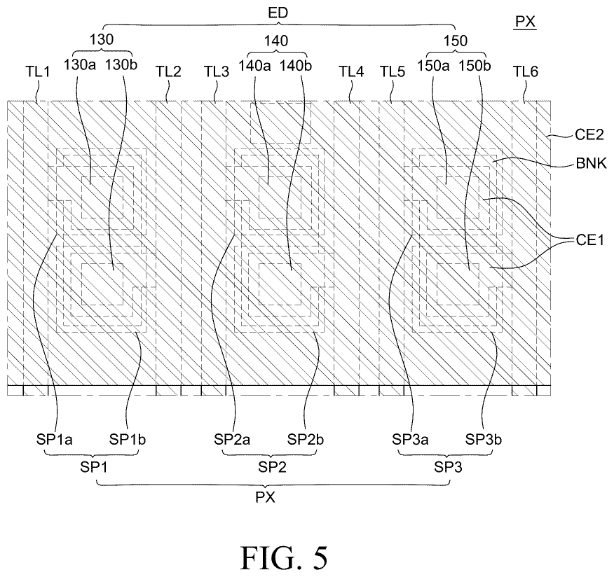

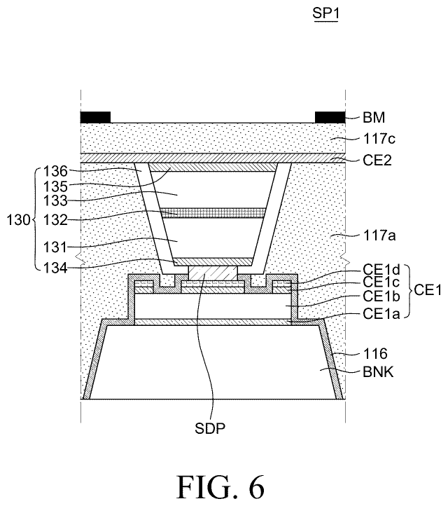

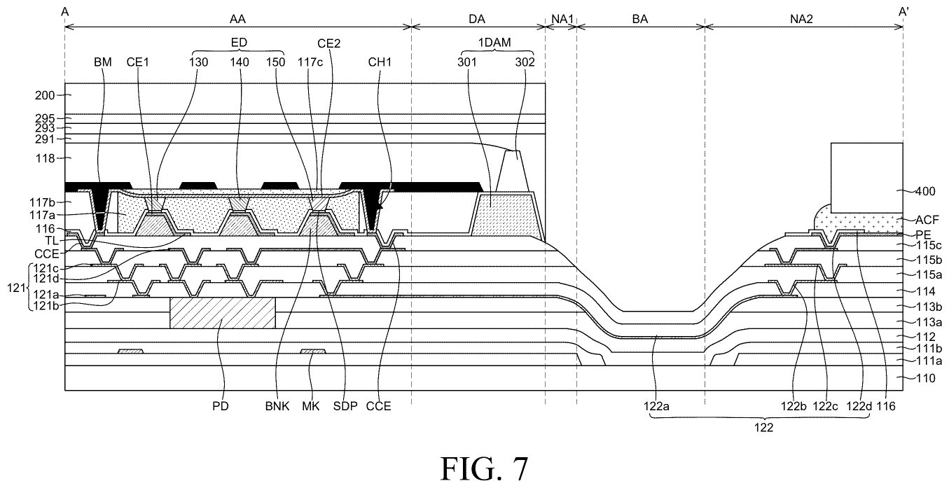

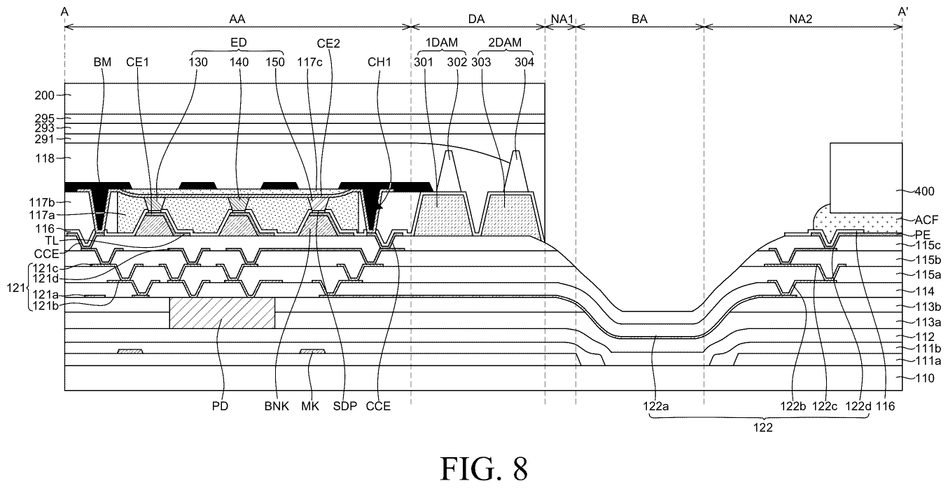

For example, FIG. 4 is an enlarged plan view of an active area including a plurality of pixels. For example, FIG. 5 is an enlarged plan view of an active area including one pixel. FIG. 6 is an enlarged cross-sectional view of a micro LED area, FIG. 7 is a cross-sectional view taken along A-A′ of FIG. 3 according to an example implementation of the present disclosure, and FIG. 8 is a cross-sectional view taken along A-A′ of FIG. 3 according to another example implementation of the present disclosure.

In FIGS. 4 and 5, a plurality of signal lines TL, a plurality of communication lines NL, a plurality of first electrodes CE1, a plurality of contact electrodes CCE, a plurality of banks BNK, a plurality of micro LEDs (ED), and a second electrode CE2 are illustrated, but the example implementations of the present disclosure are not limited thereto.

Referring to FIGS. 4 and 5, a plurality of pixels PX which is configured by a plurality of sub pixels is disposed in the active area AA. Each of the plurality of sub pixels includes a micro LED (ED) and independently emits light. The plurality of sub pixels may be disposed in a matrix by forming a plurality of rows and a plurality of columns, but the example implementations of the present disclosure are not limited thereto.

Each of the plurality of pixels PX includes one or more first sub pixels SP1, one or more second sub pixels SP2, and one or more third sub pixels SP3. For example, one pixel PX includes one pair of first sub pixels SP1, one pair of second sub pixels SP2, and one pair of third sub pixels SP3. One pair of first sub pixels SP1 is configured by a 1-1-th sub pixel SP1a and a 1-2-th sub pixel SP1b. One pair of second sub pixels SP2 is configured by a 2-1-th sub pixel SP2a and a 2-2-th sub pixel SP2b. One pair of third sub pixels SP3 is configured by a 3-1-th sub pixel SP3a and a 3-2-th sub pixel SP3b. For example, one pixel PX includes a 1-1-th sub pixel SP1a and a 1-2-th sub pixel SP1b, a 2-1-th sub pixel SP2a and a 2-2-th sub pixel SP2b, and a 3-1-th sub pixel SP3a and a 3-2-th sub pixel SP3b, but the example implementations of the present disclosure are not limited thereto.

The plurality of sub pixels which forms one pixel PX may be disposed in various ways. For example, in one pixel PX, one pair of first sub pixels SP1 is disposed in the same column, one pair of second sub pixels SP2 is disposed in the same column, and one pair of third sub pixels SP3 is disposed in the same column. The first sub pixels SP1, the second sub pixels SP2, and the third sub pixels SP3 are disposed in the same row. A number and a placement of the plurality of sub pixels which configures one pixel PX are illustrative, but the example implementations of the present disclosure are not limited thereto.

The plurality of signal lines TL is disposed in an area between the plurality of sub pixels. The plurality of signal lines TL extends in the column direction between the plurality of sub pixels. The plurality of signal lines TL may be wiring lines which transmit an anode voltage from the pixel driving circuit PD to the plurality of sub pixels. For example, the plurality of signal lines TL may be electrically connected to the plurality of pixel driving circuits PD and the first electrodes CE1 of the plurality of sub pixels. The anode voltage output from the pixel driving circuit PD is transmitted to the first electrode CE1 of the plurality of sub pixels through the plurality of signal lines TL. For example, the first electrode CE1 is an electrode which is electrically connected to the anode electrode 134 of the micro LED (ED). Therefore, the anode voltage from the signal line TL is transmitted to the anode electrode 134 of the micro LED (ED) through the first electrode CE1.

The plurality of signal lines TL includes a first signal line TL1, a second signal line TL2, a third signal line TL3, a fourth signal line TL4, a fifth signal line TL5, and a sixth signal line TL6. The first signal line TL1 and the second signal line TL2 are electrically connected to one pair of first sub pixels SP1, respectively. The third signal line TL3 and the fourth signal line TL4 are electrically connected to one pair of second sub pixels SP2, respectively. The fifth signal line TL5 and the sixth signal line TL6 are electrically connected to one pair of third sub pixels SP3, respectively.

The first signal line TL1 is disposed on one of one pair of first sub pixels SP1 and the second signal line TL2 is disposed on the other one of one pair of first sub pixels SP1. The first signal line TL1 is electrically connected to one first sub pixel SP1, between one pair of first sub pixels SP1, for example, to a first electrode CE1 of the 1-1-th sub pixel SP1a. The second signal line TL2 is electrically connected to the other first sub pixel SP1, between one pair of first sub pixels SP1, for example, to a first electrode CE1 of the 1-2-th sub pixel SP1b.

The third signal line TL3 is disposed on one of one pair of second sub pixels SP2 and the fourth signal line TL4 is disposed on the other one of one pair of second sub pixels SP2. For example, the third signal line TL3 is disposed to be adjacent to the second signal line TL2. The third signal line TL3 is electrically connected to one second sub pixel SP2, between one pair of second sub pixels SP2, for example, to a first electrode CE1 of the 2-1-th sub pixel SP2a. The fourth signal line TL4 is electrically connected to the other second sub pixel SP2, between one pair of second sub pixels SP2, for example, to a first electrode CE1 of the 2-2-th sub pixel SP2b.

The fifth signal line TL5 is disposed on one of one pair of third sub pixels SP3 and the sixth signal line TL6 is disposed on the other one of one pair of third sub pixels SP3. For example, the fifth signal line TL5 is disposed to be adjacent to the fourth signal line TL4. The sixth signal line TL6 is disposed to be adjacent to the first signal line TL1 connected to the adjacent pixel PX. The fifth signal line TL5 is electrically connected to one third sub pixel SP3, between one pair of third sub pixels SP3, for example, to a first electrode CE1 of the 3-1-th sub pixel SP3a. The sixth signal line TL6 is electrically connected to the other third sub pixel SP3, between one pair of third sub pixels SP3, for example, to a first electrode CE1 of the 3-2-th sub pixel SP3b.

The plurality of signal lines TL may be formed of a conductive material. For example, the plurality of signal lines TL is configured by a single layer or multilayered structure of a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the example implementations of the present disclosure are not limited thereto.

The plurality of communication lines NL is disposed in an area between the plurality of pixels PX. The plurality of communication lines NL is disposed to extend in the row direction in an area between the plurality of pixels PX. The plurality of communication lines NL is disposed in the area between the plurality of second electrodes CE2 and does not overlap the plurality of second electrodes CE2. For example, the plurality of communication lines NL may be wiring lines used for short distance communication, such as near field communication (NFC). The plurality of communication lines NL may serve as antennas. For example, the plurality of communication lines NL may be a plurality of connection lines, but the example implementations of the present disclosure are not limited thereto.

According to the present disclosure, a bank BNK is disposed in each of the plurality of sub pixels. The plurality of banks BNK may be structures in which the plurality of micro LEDs (ED) is seated. The plurality of banks BNK may guide a position of the plurality of micro LEDs (ED) during a transfer process of transferring the plurality of micro LEDs (ED) to the display device 1000. The plurality of micro LEDs (ED) is transferred onto the plurality of banks BNK in the transfer process of the plurality of micro LEDs (ED). The plurality of banks BNK may be a bank pattern or a structure, but the example implementations of the present disclosure are not limited thereto.

A bank BNK of the first sub pixel SP1, a bank BNK of the second sub pixel SP2, and a bank BNK of the third sub pixel SP3 are disposed to be spaced apart from each other. The bank BNK of the first sub pixel SP1, the bank BNK of the second sub pixel SP2, and the bank BNK of the third sub pixel SP3 are configured to be separated from each other. Therefore, the banks BNK of the first sub pixel SP1, the second sub pixel SP2, and the third sub pixel SP3 to which different types of micro LEDs (ED) are transferred may be easily identified.

For example, the plurality of banks BNK may be formed of an organic insulating material. The plurality of banks BNK is configured by a single layer or a double layer of an organic insulating material. For example, the plurality of banks BNK is configured by a photo resist, polyimide (PI), or acrylic material, but the example implementations of the present disclosure are not limited thereto.

The first electrode CE1 is disposed in each of the plurality of sub pixels. The first electrode CE1 is disposed on the bank BNK. For example, each of the first electrode CE1 may be disposed on a top surface and a side surface of the plurality of banks BNK.

At least a part of the first electrode CE1 extends to the outside of the bank BNK to be electrically connected to the signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL1. A part of the first electrode CE1 of the 1-2-th sub pixel SP1b extends to the other area of the 1-2-th sub pixel SP1b to be electrically connected to the second signal line TL2.

The first electrode CE1 is electrically connected to the anode electrode 134 of the micro LED (ED) and transmits an anode voltage from the pixel driving circuit PD to the micro LED (ED) of each of the plurality of sub pixels through the signal line TL. Different voltages may be applied to the first electrodes CE1 of the plurality of sub pixels depending on the image to be displayed. For example, different voltages may be applied to the first electrodes CE1 of the plurality of sub pixels. Therefore, the first electrode CE1 may be a pixel electrode, but the example implementations of the present disclosure are not limited thereto.

The plurality of micro LEDs (ED) includes a first micro LED 130, a second micro LED 140, and a third micro LED 150. The first micro LED 130 is disposed in the first sub pixel SP1. The second micro LED 140 is disposed in the second sub pixel SP2. The third micro LED 150 is disposed in the third sub pixel SP3. For example, any one of the first micro LED 130, the second micro LED 140, and the third micro LED 150 is a red micro LED, another is a green micro LED, and the third is a blue micro LED, but the example implementations of the present disclosure are not limited thereto. Therefore, red light, green light, and blue light emitted from the plurality of micro LEDs (ED) are combined to implement various color light including white. The types of the plurality of micro LEDs (ED) are illustrative, but the example implementations of the present disclosure are not limited thereto.

The second electrode CE2 is disposed in each of the plurality of sub pixels. The second electrode CE2 is disposed on the micro LED (ED). The second electrode CE2 is electrically connected to the pixel driving circuit PD through the plurality of contact electrodes CCE.

For example, the second electrode CE2 is electrically connected to the cathode electrode 135 of the micro LED (ED) to transmit a cathode voltage from the pixel driving circuit PD to the micro LED (ED). The same cathode voltage may be applied to the second electrodes CE2 of the plurality of sub pixels. For example, the same voltage is applied to the second electrode CE2 of each of the plurality of sub pixels and the cathode electrode 135 of the micro LED (ED). Therefore, the second electrode CE2 may be a common electrode, but the example implementations of the present disclosure are not limited thereto.

At least some of the plurality of sub pixel shares the second electrode CE2. At least some of the second electrodes CE2 of the plurality of sub pixels may be electrically connected to each other. As the same voltage is applied to the second electrode CE2, the second electrodes CE2 of at least some of sub pixels are shared. For example, the second electrodes CE2 of at least some pixels PX, among the plurality of pixels PX disposed on the same row, are connected to each other. For example, one second electrode CE2 is disposed in the plurality of pixels PX. One second electrode CE2 is disposed in every n sub pixels.

For example, some of the second electrodes CE2 of the plurality of sub pixels is disposed to be spaced apart or separated from each other. For example, a second electrode CE2 connected to pixels PX in a n-th row and a second electrode CE2 connected to pixels PX in a n+1-th row are disposed to be spaced apart or separated from each other. For example, the plurality of second electrodes CE2 is disposed to be spaced apart from each other with the plurality of communication lines NL extending in the row direction therebetween.

The plurality of second electrodes CE2 is configured by a transparent conductive material so that light emitted from the micro LED (ED) travels toward the top of the second electrode CE2. For example, the second electrode CE2 is configured by a transparent conductive material, such as indium tin oxide (ITO), indium zinc oxide (IZO), indium gallium zinc oxide (IGZO), but the example implementations of the present disclosure are not limited thereto.

A plurality of contact electrodes CCE is disposed on the substrate 110. For example, the plurality of contact electrodes CCE is disposed to be spaced apart from the plurality of banks BNK and the plurality of signal lines TL. Each of the plurality of second electrodes CE2 overlaps at least one contact electrode CCE. For example, one second electrode CE2 overlaps a plurality of contact electrodes CCE.

For example, the plurality of contact electrodes CCE is electrically connected to the plurality of second electrodes CE2. The plurality of contact electrodes CCE is disposed between the substrate 110 and the plurality of second electrodes CE2 to transmit a cathode voltage from the pixel driving circuit PD to the second electrode CE2.

When a micro LED is used as the micro LED (ED), a plurality of micro LEDs is formed on a wafer and the micro LED is transferred onto the substrate 110 of the display device 1000 to manufacture the display device 1000. However, during the process of transferring the plurality of micro LEDs (ED) having a micro size from the wafer to the substrate 110, various defects may be caused. For example, in some sub pixel, a non-transfer defect in which the micro LED is not transferred may occur and in the other sub pixel, a defect that the micro LED (ED) is transferred in a wrong position may occur due to the alignment error. Further, even though the transfer process is normally performed, the transferred micro LED (ED) may be defective. Accordingly, in consideration of the defects during the transfer process of the plurality of micro LEDs (ED), a plurality of micro LEDs which emits the same color light may be transferred into one sub pixel. A lighting test for the plurality of micro LEDs (ED) is performed and only one micro LED (ED) which is finally determined to be normal may be used.

For example, the 1-1-th micro LED 130a and the 1-2-th micro LED 130b are transferred to one pixel PX together and defects thereof are tested. If both the 1-1-th micro LED 130a and the 1-2-th micro LED 130b are determined to be normal, only the 1-1-th micro LED 130a is used, but the 1-2-th micro LED 130b is not used. Accordingly, even though the plurality of micro LEDs (ED) which emits the same color light is transferred into one pixel PX, finally, only one micro LED (ED) is used.

Therefore, any one of one pair of micro LEDs (ED) is a main (or primary) micro LED (ED) and the other micro LED ED) is a redundancy micro LED (ED). The redundancy micro LED (ED) may be an extra micro LED (ED) which is transferred to prepare for a defect of the main micro LED(ED) . When the main micro LED (ED) is defective, the redundancy micro LED (ED) may be used instead. Accordingly, the main micro LED (ED) and the redundancy micro LED (ED) are transferred together to one pixel PX so that the degradation of the display quality due to the defects of the main micro LED (ED) and the redundancy micro LED (ED) may be minimized or reduced.

Finally, the black matrix BB is formed in an active area AA and a non-active area NA excluding an emission area of the micro LED used in each sub pixel, between the redundancy micro LED (ED) or the main micro LED (ED), to suppress light emitted from a micro LED which is not used in each sub pixel from being emitted upwardly.

FIG. 6 is an enlarged view of a light emitting diode according to an example implementation of the present disclosure. Referring to FIG. 6, the first micro LED 130 which is a light emitting diode includes an anode electrode 134, a first semiconductor layer 131, an active layer 132, a second semiconductor layer 133, a cathode electrode 135, and an encapsulation film 136, but the example implementations of the present disclosure are not limited thereto. For example, the encapsulation film 136 may not be included in the first micro LED 130.

For example, one of the first semiconductor layer 131 and the second semiconductor layer 133 may be implemented by a compound semiconductor, such as a III-V group or a II-VI group and is doped with an impurity (or dopant). For example, one of the first semiconductor layer 131 and the second semiconductor layer 133 is an n-type impurity doped semiconductor layer and the other one is a p-type impurity doped semiconductor, but the example implementations of the present disclosure are not limited thereto. For example, one or more of the first semiconductor layer 131 and the second semiconductor layer 133 may be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the example implementations of the present disclosure are not limited thereto.

The active layer 132 is disposed between the first semiconductor layer 131 and the second semiconductor layer 133. The active layer 132 is supplied with holes and electrons from the first semiconductor layer 131 and the second semiconductor layer 133 to emit light. For example, the active layer 132 may be configured by a single well structure, a multi-well structure, a signal quantum well structure, a multi-quantum well (MQC) structure, a quantum dot structure, and a quantum line structure, but the example implementations of the present disclosure are not limited thereto. For example, the active layer 132 may be configured by indium gallium nitride (InGaN) or gallium nitride (GaN), but the example implementations of the present disclosure are not limited thereto.

The anode electrode 134 is disposed below the first semiconductor layer 131. The anode electrode 134 is formed of a conductive material which is eutectically bondable to the solder pattern SDP. For example, the anode electrode 134 may be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the example implementations of the present disclosure are not limited thereto.

The cathode electrode 135 is disposed on the second semiconductor layer 133. For example, the cathode electrode 135 electrically connects the second semiconductor layer 133 and the second electrode CE2. A cathode voltage output from the pixel driving circuit PD is applied to the second semiconductor layer 133 through the contact electrode CCE, the second electrode CE2, and the cathode electrode 135. The cathode electrode 135 may be configured by a transparent conductive material to allow light emitted from the micro LED (ED) to be directed to the top of the micro LED (ED), but the example implementations of the present disclosure are not limited thereto. For example, the cathode electrode 135 is configured by a material, such as indium tin oxide (ITO), indium zinc oxide (IZO), indium gallium zinc oxide (IGZO), but the example implementations of the present disclosure are not limited thereto.

The encapsulation film 136 is disposed in at least a part of the first semiconductor layer 131, the active layer 132, the second semiconductor layer 133, the anode electrode 134, and the cathode electrode 135. For example, the encapsulation film 136 encloses at least a part of the first semiconductor layer 131, the active layer 132, the second semiconductor layer 133, the anode electrode 134, and the cathode electrode 135.

For example, the encapsulation film 136 protects the first semiconductor layer 131, the active layer 132, and the second semiconductor layer 133. For example, the encapsulation film 136 is disposed on a side surface of the first semiconductor layer 131, a side surface of the active layer 132, and a side surface of the second semiconductor layer 133. For example, the encapsulation film 136 is formed of an insulating material, such as silicon nitride (SiNx) or silicon oxide (SiOx), but the example implementations of the present disclosure are not limited thereto.

FIG. 7 is a cross-sectional view taken along A-A′ of FIG. 3. FIG. 7 is a cross-sectional view of an active area AA, a dam area DA, a first non-active area NA1, a bending area BA, and a second non-active area NA2 according to an example implementation of the present disclosure.

In the meantime, for the convenience of illustration, in FIG. 3, it is illustrated that a trimming line of A-A′ and a driving line VL and a link line LL do not overlap, but the trimming line A-A′ of FIG. 3 is provided to represent the same position as the adjacent driving line VL and link line LL.

Referring to FIG. 7, a first buffer layer 111a and a second buffer layer 111b are disposed in the remaining area of the substrate 110 excluding the bending area BA.

The first buffer layer 111a and the second buffer layer 111b are disposed in the active area AA, the dam area DA, the first non-active area NA1, and the second non-active area NA2. The first buffer layer 111a and the second buffer layer 411b may reduce permeation of moisture or impurities through the substrate 110. The first buffer layer 111a and the second buffer layer 111b may be formed of an inorganic insulating material. For example, the first buffer layer 111a and the second buffer layer 111b may be configured by a single layer or multiple layers of silicon oxide (SiOx) or silicon nitride (SiNx), but the example implementations of the present disclosure are not limited thereto.

For example, a part of the first buffer layer 111a and the second buffer layer 111b on the bending area BA may be removed. A top surface of the substrate 110 located in the bending area BA may be exposed from the first buffer layer 111a and the second buffer layer 111b. The first buffer layer 111a and the second buffer layer 111b which are formed of an inorganic insulating material are removed from the bending area BA to minimize or reduce cracks of the first buffer layer 111a and the second buffer layer 111b which may be generated during the bending.

A plurality of alignment keys MK may be disposed between the first buffer layer 111a and the second buffer layer 111b. The plurality of alignment keys MK may be configured to identify a position of the pixel driving circuit PD during the fabricating process of the display device 1000. For example, the plurality of alignment keys MK may be configured to align a position of the pixel driving circuit PD which is transferred onto the adhesive layer 112. As another example, the plurality of alignment keys MK may be omitted.

The adhesive layer 112 may be disposed on the second buffer layer 111b. The adhesive layer 112 may be disposed in the active area AA, the dam area DA, the first non-active area NA1, the bending area BA, and the second non-active area NA2. As another example, in the non-active area NA including the bending area BA, at least a part of the adhesive layer 112 may be removed. For example, the adhesive layer 112 may be formed of any one of adhesive polymer, epoxy resin, UV curable resin, polyimide based, acrylate based, urethane based, and polydimethylsiloxane (PDMS), but the example implementations of the present disclosure are not limited thereto.

The pixel driving circuit PD is disposed on the adhesive layer 112 in the active area AA. When the pixel driving circuit PD is implemented as a driving driver, the driving driver may be mounted on the adhesive layer 112 by the transfer process, but the example implementations of the present disclosure are not limited thereto.

A first protection layer 113a and a second protection layer 113b are disposed on top surfaces or side surfaces of the adhesive layer 112 and the pixel driving circuit PD. The first protection layer 113a and the second protection layer 113b are disposed so as to enclose the side surface of the pixel driving circuit PD, but the example implementations of the present disclosure are not limited thereto. For example, the second protection layer 113b may be disposed so as to cover at least a part of a top surface of the pixel driving circuit PD.

For example, at least one of the first protection layer 113a and the second protection layer 113b disposed on the bending area BA may be omitted. For example, the first protection layer 113a is entirely disposed in the active area AA, the dam area DA, and the non-active area NA and the second protection layer 113b is partially disposed in the active area AA, the dam area DA, the first non-active area NA1, and the second non-active area NA2. For example, a part of the second protection layer 113b in the bending area BA may be removed, but the example implementations of the present disclosure are not limited thereto.

The first protection layer 113a and the second protection layer 113b may be configured by an organic insulating material, but the example implementations of the present disclosure are not limited thereto. For example, the first protection layer 113a and the second protection layer 113b are configured by a photo resist, polyimide (PI), or photo acrylic material, but the example implementations of the present disclosure are not limited thereto. For example, the first protection layer 113a and the second protection layer 113b may be over coating layers or insulating layers, but the example implementations of the present disclosure are not limited thereto.

According to the present disclosure, in the active area AA, the plurality of first connection lines 121 may be disposed on the second protection layer 113b. The plurality of first connection lines 121 may be wiring lines which electrically connect the pixel driving circuit PD to the other component. For example, the pixel driving circuit PD may be electrically connected to the plurality of signal lines TL and the plurality of contact electrodes CCE through the plurality of first connection lines 121. For example, the plurality of first connection lines 121 includes a 1-1-th connection line 121a, a 1-2-th connection line 121b, a 1-3-th connection line 121c, and a 1-4-th connection line 121d. The 1-1-th connection line 121a, the 1-2-th connection line 121b, the 1-3-th connection line 121c, and the 1-4-th connection line 121d are electrically connected through a contact hole formed in an insulating layer between connection lines, but the example implementations of the present disclosure are not limited thereto. Each of the plurality of first connection lines 121 refers to a signal line disposed on the same layer and the plurality of first connection lines 121 includes signal lines to which different signals are applied.

For example, a third protection layer 114 may be disposed on the second protection layer 113b. The third protection layer 114 is entirely disposed in the active area AA, the dam area DA, and the non-active area NA.

In the bending area BA, the third protection layer 114 may cover a side surface of the second protection layer 113b and the top surface of the first protection layer 113a. The third protection layer 114 may be configured by an organic insulating material. For example, the third protection layer 114 is configured by a photo resist, polyimide (PI), or photo acrylic material, but the example implementations of the present disclosure are not limited thereto. For example, the first protection layer 113a, the second protection layer 113b, and the third protection layer 114 may be configured by the same material, but the example implementations of the present disclosure are not limited thereto.

A plurality of 1-2-th connection lines 121b may be disposed on the third protection layer 114 and the first insulating layer 115a is disposed on the plurality of 1-2-th connection lines 121b. The first insulating layer 115a is entirely disposed in the active area AA and the non-active area NA, but the example implementations of the present disclosure are not limited thereto. The first insulating layer 115a is configured by an organic insulating material, but the example implementations of the present disclosure are not limited thereto. For example, the first insulating layer 115a is configured by a photo resist, polyimide (PI), or photo acrylic material, but the example implementations of the present disclosure are not limited thereto.

The plurality of 1-3-th connection lines 121c may be disposed on the first insulating layer 115a. The plurality of 1-3-th connection lines 121c is electrically connected to the plurality of 1-2-th connection lines 121b. For example, the 1-3-th connection lines 121c may be electrically connected to the 1-2-th connection line 121b through a contact hole of the first insulating layer 115a.

The second insulating layer 115b is disposed on the plurality of 1-3-th connection lines 121c. The second insulating layer 115b may be disposed in a remaining area excluding the bending area BA, but the example implementations of the present disclosure are not limited thereto. The second insulating layer 115b may be disposed in the active area AA, the first non-active area NA1, and the second non-active area NA2, but the example implementations of the present disclosure are not limited thereto. For example, a part of the second insulating layer 115b disposed in the bending area BA may be removed. The second insulating layer 115b is configured by an organic insulating material, but the example implementations of the present disclosure are not limited thereto. For example, the second insulating layer 115b is configured by a photo resist, polyimide (PI), or photo acrylic material, but the example implementations of the present disclosure are not limited thereto.

The plurality of 1-4-th connection lines 121d may be disposed on the second insulating layer 115b. The plurality of 1-4-th connection lines 121d is electrically connected to the plurality of 1-3-th connection lines 121c. For example, the 1-4-th connection lines 121d may be electrically connected to the 1-3-th connection line 121c through a contact hole of the second insulating layer 115b.

A plurality of signal lines TL is disposed on the third insulating layer 115c in the active area AA. The plurality of signal lines TL is disposed to extend to an area between the plurality of banks BNK. For example, the plurality of signal lines TL is disposed to be adjacent to any one of the plurality of banks BNK.

According to the present disclosure, in the non-active area NA, the plurality of second connection lines 122 may be disposed on the second protection layer 113b. The plurality of second connection lines 122 may be wiring lines which transmit a signal transmitted from the flexible circuit board (or flexible film) 400 and the printed circuit board 500 (see FIG. 1) to the pad unit PAD to the pixel driving circuit PD of the active area AA. For example, the plurality of second connection lines 122 is electrically connected to the plurality of pad electrodes PE to be applied with a signal from the flexible circuit board (or flexible film) 400 and the printed circuit board 500.

For example, the plurality of second connection lines 122 extends toward the active area AA from the pad unit PAD to transmit a signal to the wiring line of the active area AA. In this case, the plurality of second connection lines 122 may serve as link lines LL. The plurality of second connection lines 122 includes a 2-1-th connection line 122a, a 2-2-th connection line 122b, a 2-3-th connection line 122c, and a 2-4-th connection line 122d. Accordingly, a signal from the flexible circuit board (or flexible film) 400 and the printed circuit board 500 may be transmitted to the 2-1-th connection line 122a through the 2-4-th connection line 122d, the 2-3-th connection line 122c, and the 2-2-th connection line 122b.

The plurality of first connection lines 121 and the plurality of second connection lines 122 may be formed of any one of a conductive material having excellent ductility or various conductive materials used for the active area AA.

For example, the plurality of first connection lines 121 and the plurality of second connection lines 122 may be configured by molybdenum (Mo), chrome (Cr), titanium (Ti), nickel (Ni), neodymium (Nd), copper (Cu), and an alloy of silver (Ag) and magnesium (Mg) or an alloy thereof, but the example implementations of the present disclosure are not limited thereto.

The third insulating layer 115c may be disposed on the plurality of first connection lines 121 and the plurality of second connection lines 122. The third insulating layer 115c may be disposed in a remaining area excluding the bending area BA, but the example implementations of the present disclosure are not limited thereto. The third insulating layer 115c is disposed in the active area AA, the dam area DA, the first non-active area NA1, and the second non-active area NA2. A part of the third insulating layer 115c disposed in the bending area BA may be removed. The third insulating layer 115c is configured by an organic insulating material, but the example implementations of the present disclosure are not limited thereto. For example, the third insulating layer 115c is configured by a photo resist, polyimide (PI), or photo acrylic material, but the example implementations of the present disclosure are not limited thereto.

In the bending area BA, the substrate 110 is bent so that the second non-active area NA2 at least partially overlaps the active area AA. In order to allow the substrate 110 to be bent, a layer disposed on the substrate 110 may be minimized to suppress the crack. Therefore, in the bending area BA, the first buffer layer 111a, the second buffer layer 111b, the second protection layer 113b, the second insulating layer 115b or the third insulating layer 115c is not formed, but the example implementations of the present disclosure are not limited thereto.

For example, when an end of the first buffer layer 111a, the second buffer layer 111b, the second protection layer 113b, the second insulating layer 115b, or the third insulating layer 115c which may be formed of an organic material is patterned so as not to be formed in the bending area BA, the first buffer layer 111a, the second buffer layer 111b, the second protection layer 113b, the second insulating layer 115b, or the third insulating layer 115c has an end which is patterned to have a thickness which is reduced toward an end as compared with the thickness of layers disposed in the active area. Therefore, the step and the thickness are changed.

By doing this, the adhesive layer 112, the first protection layer 113a, the first insulating layer 115a, and the third insulating layer 115c disposed below or above the first buffer layer 111a, the second buffer layer 111b, the second protection layer 113b, the second insulating layer 115b, or the third insulating layer 115c are inclined with an inclination angle toward the bending area along thicknesses of the lower layers which are reduced.

A plurality of banks BNK is disposed on the third insulating layer 115c in the active area AA. The plurality of banks BNK is disposed so as to overlap each of the plurality of sub pixels. One or more micro LEDs (ED) which emit the same color light may be disposed above each of the plurality of banks BNK.

The plurality of banks BNK is configured by a photo resist, polyimide (PI), or photo acrylic material, but the example implementations of the present disclosure are not limited thereto.

The dam area DA is disposed between the active area AA and the bending area BA, and specifically, is disposed between the active area AA and the first non-active area NA1. The dam area DA may include an inclined portion along slopes of lower insulating layers, but the example implementations of the present disclosure are not limited thereto.

In the dam area DA, a first dam 1DAM is disposed. The first dam 1DAM includes a first dam layer 301 which is formed with the same material by the same process as the plurality of banks BNK. The plurality of banks BNK and the first dam layer 301 are formed by the half-tone mask process to have different heights and widths. A height of the first dam layer 301 is higher than that of the plurality of banks BNK and a width of the first dam layer 301 may be larger than that of the plurality of banks BNK, but the example implementations of the present disclosure are not limited thereto.

A plurality of contact electrodes CCE is disposed on the third insulating layer 115c in the active area AA. The plurality of contact electrodes CCE supplies a cathode voltage from the pixel driving circuit PD to the second electrode CE2.

The first electrode CE1 is disposed on the bank BNK. For example, the first electrode CE1 is disposed to extend toward the top of the bank BNK from the adjacent signal line TL. The first electrode CE1 is disposed on the top surface of the bank BNK and the side surface of the bank BNK. For example, the first electrode CE1 is disposed to extend from the signal line TL on the top surface of the third insulating layer 115c to the side surface of the bank BNK and the top surface of the bank BNK.

The first electrode CE1 is configured by a plurality of conductive layers. For example, the first electrode CE1 includes a first conductive layer CE1a, a second conductive layer CE1b, a third conductive layer CE1c, and a fourth conductive layer CE1d, but the example implementations of the present disclosure are not limited thereto.

The first conductive layer CE1a is disposed on the bank BNK. The second conductive layer CE1b is disposed on the first conductive layer CE1a. The third conductive layer CE1c is disposed on the second conductive layer CE1b. The fourth conductive layer CE1d is disposed on the third conductive layer CE1c. For example, the first conductive layer CE1a, the second conductive layer CE1b, the third conductive layer CE1c, and the fourth conductive layer CE1d are configured by titanium (Ti), molybdenum (Mo), aluminum (Al), or titanium (Ti) and indium tin oxide (ITO), but the example implementations of the present disclosure are not limited thereto.

According to the present disclosure, some conductive layer having a good reflection efficiency, among a plurality of conductive layers which configures the first electrode CE1, may be configured as an alignment key for alignment of the micro LED (ED) and/or a reflective plate.

For example, in order to configure the second conductive layer CE1b as a reflective plate, the third conductive layer CE1c and the fourth conductive layer CE1d which cover the second conductive layer CE1b may be partially removed or etched. For example, a part of the third conductive layer CE1c and the fourth conductive layer CE1d disposed on the bank BNK is removed or etched to expose a top surface of the second conductive layer CE1b. For example, a center portion and an edge portion of the third conductive layer CE1c and the fourth conductive layer CE1d in which a solder pattern SDP is disposed remain and the remaining portion excluding this portion may be removed. For example, an edge portion of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 may be suppressed.

According to the present disclosure, the first conductive layer CE1a and the third conductive layer CE1c include titanium (Ti) or molybdenum (Mo). The second conductive layer CE1b includes aluminum (Al). The fourth conductive layer CE1d includes a transparent conductive oxide layer, such as indium tin oxide (ITO) or indium zinc oxide (IZO), which is adhesive to the solder pattern SPD, and has anti-corrosion and acid resistance, but the example implementations of the present disclosure are not limited thereto.

According to the present disclosure, the signal line TL, the contact electrode CCE, and the pad electrode PE disposed on the same layer as the first electrode CE1 may be configured by multiple layers of conductive materials, but the example implementation of the present disclosure is not limited thereto.

According to the present disclosure, in each of the plurality of sub pixels, a solder pattern SDP is disposed on the first electrode CE1. The solder pattern SDP bonds the micro LED (ED) to the first electrode CE1 to electrically connect the first electrode CE1 and the micro LED (ED). For example, the first electrode CE1 and the anode electrode 134 of the micro LED (ED) may be electrically connected through eutectic bonding using the solder pattern SDP, but the example implementations of the present disclosure are not limited thereto. For example, when the solder pattern SDP is configured by indium (In) and the anode electrode 134 of the micro LED (ED) is configured by gold (Au), during the transfer process of the micro LED (ED), heat and pressure are applied to bond the solder pattern SDP and the anode electrode 134. The micro LED (ED) is bonded to the solder pattern SDP and the first electrode CE1 using the eutectic bonding without a separate adhesive material. For example, the solder pattern SDP may be configured by indium (Id), tin (Sn), or an alloy thereof, but the example implementations of the present disclosure are not limited thereto. For example, the solder pattern SDP may be a bonding pad or an adhesive pad, but the example implementations of the present disclosure are not limited thereto.

According to the present disclosure, the passivation layer 116 is disposed on the plurality of signal lines TL, the plurality of first electrodes CE1, the plurality of contact electrodes CCE, and the third insulating layer 115c. For example, the passivation layer 116 is disposed in the active area AA, the dam area DA, the first non-active area NA1, and the second non-active area NA2. In the dam area DA, the passivation layer 116 is disposed on the first dam layer 301. A part of the passivation layer 116 disposed in the bending area BA may be removed. A part of the passivation layer 116 which covers a plurality of pad electrodes PE in the second non-active area NA2 may be removed. The passivation layer 116 is disposed so as to cover the remaining area excluding the bending area BA, the plurality of pad electrodes PE, and the solder pattern SDP to reduce permeation of moisture or impurities entering the micro LED (ED). For example, the passivation layer 116 may be configured by a single layer or multiple layers of silicon oxide (SiOx) or silicon nitride (SiNx), but the example implementations of the present disclosure are not limited thereto.

In each of the plurality of sub pixels, the micro LED (ED) is disposed on the solder pattern SDP. A first micro LED 130 is disposed in the first sub pixel SP1. A second micro LED 140 is disposed in the second sub pixel SP2.

According to the present disclosure, in the active area AA, a first optical layer 117a which encloses the plurality of micro LEDs (ED) may be disposed. For example, the first optical layer 117a may be disposed so as to cover the plurality of micro LEDs (ED) and the bank BNK in the area of the plurality of sub pixels. For example, the first optical layer 117a may cover a part of the passivation layer 116 and between the plurality of micro LEDs (ED). The first optical layer 117a may be disposed or cover between the plurality of micro LEDs (ED) and between the plurality of banks BNK included in one pixel PX. For example, the first optical layer 117a extends in a first direction and is spaced apart from each other in a second direction which intersects the first direction. For example, the first optical layer 117a is disposed so as to enclose side portions of the micro LED (ED) and the bank BNK between the passivation layer 116 and the second electrode CE2, but the example implementations of the present disclosure are not limited thereto. For example, the first optical layer 117a may be a diffusion layer or a side wall diffusion layer, but the example implementations of the present disclosure are not limited thereto.

The first optical layer 117a includes an organic insulating material in which micro particles are dispersed, but the example implementations of the present disclosure are not limited thereto. For example, the first optical layer 117a may be configured by siloxane in which micro metal particles, such as titanium dioxide (TiO2) particles, are dispersed, but the example implementations of the present disclosure are not limited thereto. Light from the plurality of micro LEDs (ED) is scattered by micro particles dispersed in the first optical layer 117a to be emitted to the outside of the display device 1000. Accordingly, the first optical layer 117a may improve extraction efficiency of light emitted from the plurality of micro LEDs (ED).

For example, the first optical layer 117a may be disposed in each of the plurality of pixels PX or disposed in some pixel PX disposed in the same row together, but the example implementations of the present disclosure are not limited thereto. For example, the first optical layer 117a is disposed in each of the plurality of pixels PX or the plurality of pixels PX may share one first optical layer 117a. As another example, each of the plurality of sub pixels separately includes the first optical layer 117a, but the example implementations of the present disclosure are not limited thereto.

A second optical layer 117b is disposed on the passivation layer 116 on which the first optical layer 117a is not disposed. For example, the second optical layer 117b may be disposed so as to enclose the first optical layer 117a. For example, the second optical layer 117b may be in contact with a side surface of the first optical layer 117a. For example, the second optical layer 117b may be disposed in an area between the plurality of pixels PX. However, the example implementations of the present disclosure are not limited thereto. For example, the second optical layer 117b may be a diffusion layer, a diffusion window, or a window diffusion layer, but the example implementations of the present disclosure are not limited thereto.

The second optical layer 117b is configured by an organic insulating material, but the example implementations of the present disclosure are not limited thereto. The second optical layer 117b is configured by the same material as the first optical layer 117a, but the example implementations of the present disclosure are not limited thereto. For example, the first optical layer 117a may include micro particles, but the second optical layer 117b does not include micro particles. For example, the second optical layer 117b is configured by siloxane, but the example implementations of the present disclosure are not limited thereto.

The second optical layer 117b is not disposed in the bending area BA, the first non-active area NA1, and a second non-active area NA2. The second optical layer 117b is disposed in the active area AA and the dam area DA.

The first dam 1DAM of the dam area DA further includes a second dam layer 302 disposed on the first dam layer 301.

The second dam layer 302 may be formed of the same material by the same process as the second optical layer 117b.

The cathode electrode (135 of FIG. 6) of the micro LED (ED) is exposed to partially remove the first optical layer 117a on the cathode electrode 135 for connection with the second electrode CE2 thereafter. Referring to FIG. 7, a mask process for forming a contact hole CH1 in the second optical layer 117b is performed for the second electrode CE2 and a plurality of contact electrodes CCE. At this time, the second dam layer 302 is formed on the first dam layer 301.

The second dam layer 302 has a width smaller than the first dam layer 301, but the example implementations of the present disclosure are not limited thereto.

The first dam layer 301 of the first dam 1DAM formed in the dam area DA suppresses the end of the second optical layer 117b adjacent to the bending area BA from being thinner along an inclined surface due to the slope caused by the insulating layers therebelow. A side portion of the first dam layer 301 closer to the active area AA may suppress the flow of the second optical layer 117b.

By doing this, the thickness change of the second optical layer 117b in a center portion and an outer peripheral portion of the active area AA is minimized to uniformize the light emission efficiency in the entire active area AA.

The second electrode CE2 is formed above the micro LED (ED), the first optical layer 117a, and the second optical layer 117b of the active area AA and in the contact hole CH1.

For example, the second electrode CE2 may be electrically connected to the plurality of contact electrodes CCE through the contact hole CH1 of the second optical layer 117b. The second electrode CE2 is disposed on the plurality of micro LEDs (ED) to be electrically connected to the cathode electrode 135. For example, the second electrode CE2 includes a transparent conductive oxide, such as indium tin oxide (ITO) or indium zinc oxide (IZO), but the example implementations of the present disclosure are not limited thereto.

The third optical layer 117c is disposed on the second electrode CE2. The third optical layer 117c is disposed so as to overlap the plurality of micro LEDs (ED) and the first optical layer 117a. The third optical layer 117c is disposed above the second electrode CE2 and the plurality of micro LEDs (ED) to improve a mura which may occur in a part of the plurality of micro LEDs (ED). Further, light emitted from the plurality of micro LEDs (ED) is uniformly dispersed by the third optical layer 117c to be extracted to the outside of the display device 1000 so that the luminance uniformity of the display device 1000 may be improved.

The third optical layer 117c is configured by an organic insulating material in which micro particles are dispersed, but the example implementations of the present disclosure are not limited thereto. For example, the third optical layer 117c may be configured by siloxane in which micro metal particles, such as titanium dioxide (TiO2) particles, are dispersed, but the example implementations of the present disclosure are not limited thereto. For example, the third optical layer 117c is configured by the same material as the first optical layer 117a, but the example implementations of the present disclosure are not limited thereto. For example, the third optical layer 117c may be a diffusion layer or an upward diffusion layer, but the example implementations of the present disclosure are not limited thereto.

In the active area AA, a black matrix BM is disposed on the second electrode CE2, the first optical layer 117a, the second optical layer 117b, and the third optical layer 117c and the black matrix BM is formed to be filled in the contact hole CH1.

For example, the contact hole of the second optical layer 117b may be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels is suppressed.

The black matrix BM extends to the dam area DA. The black matrix BM is disposed on at least a part of the first dam layer 301.

When the black matrix BM is formed of an organic material, the black matrix BM is also thin along a lower boundary surface. When the black matrix BM is thin, light leakage of the micro LED (ED) occurs in the bending area BA.

The black matrix BM extends onto the first dam layer 301 having a predetermined height so that the black matrix BM is suppressed from flowing along the inclined surface to reduce the thickness.

When the passivation layer 116 is disposed on the first dam layer 301, the black matrix BM is disposed to be in direct contact with at least a part of the upper surface of the passivation layer 116, but the example implementations of the present disclosure are not limited thereto.

For example, the black matrix BM may be configured by an opaque material, but the example implementations of the present disclosure are not limited thereto. For example, the black matrix BM may be configured by an organic insulating material to which black pigment or black dye is added, but the example implementations of the present disclosure are not limited thereto.

In the active area AA, a cover layer 118 is disposed on the black matrix BM. The cover layer 118 protects configurations below the cover layer 118. For example, the cover layer 118 is configured by an organic insulating material, but the example implementations of the present disclosure are not limited thereto. For example, the cover layer 118 is configured by a photo resist, polyimide (PI), or photo acrylic material, but the example implementations of the present disclosure are not limited thereto. For example, the cover layer 118 may be an over coating layer or an insulating layer, but the example implementations of the present disclosure are not limited thereto.

The cover layer 118 has an inclined surface in the dam area DA and a thickness thereof is gradually reduced. The cover layer 118 is at least partially disposed above the first dam 1DAM and an end of the cover layer 118 is disposed on the second dam layer 302 of the first dam 1DAM so as not to overflow to the bending area BA.

The cover layer 118 is disposed to be thicker than the adhesive layer 112, the first protection layer 113a, the third protection layer 114, the first insulating layer 115a disposed in the bending area BA so as to protect the micro LED (ED) of the active area AA and the electrodes. When the cover layer 118 overflows to the bending area BA, a total thickness of layers disposed in the bending area BA is increased so that a bending defect may occur.

A polarization layer 293 is disposed on the cover layer 118 by means of the first adhesive layer 291. A cover member 200 is disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the example implementations of the present disclosure are not limited thereto.

FIG. 8 is a cross-sectional view taken along A-A′ of FIG. 3 according to another example implementation of the present disclosure.

Components which are the same as or correspond to components of FIG. 7, among components illustrated in FIG. 8, will not be described or simplified.

A first dam 1DAM and a second dam 2DAM are disposed on the third insulating layer 115c in the dam area DA. A dam of the dam area DA may be additionally disposed if necessary depending on the design.

The second dam 2DAM includes a third dam layer 303 and a fourth dam layer 304 disposed on the third dam layer 303, but is not limited thereto. The third dam layer 303 is formed of the same material by the same process as the plurality of banks BNK and the first dam layer 301 of the first dam 1DAM.

A height of the first dam layer 301 and a height of the third dam layer 303 are equal to each other and a width of the first dam layer 301 and a width of the third dam layer 303 are different from each other, but the example implementations of the present disclosure are not limited thereto.

For example, a width of the first dam layer 301 is larger than a width of the third dam layer 303 so that the first dam layer 301 of the first dam 1DAM stably supports an end of the second optical layer 117b.

A fourth dam layer 304 of the second dam 2DAM is formed of the same material by the same process as the second dam layer 302 and the second optical layer 117b.

The fourth dam layer 304 may be formed to have the same height as the second dam layer 302 and the second optical layer 117b and have different widths, but the example implementations of the present disclosure are not limited thereto.

The passivation layer 116 may be disposed to extend to the second dam 2DAM of the dam area DA. The passivation layer 116 may be disposed between the first dam layer 301 and the second dam layer 302 of the first dam 1DAM and between the third dam layer 303 and the fourth dam layer 304 of the second dam 2Dam, but the example implementations of the present disclosure are not limited thereto.

The cover layer 118 may be formed to extend to the second dam 2DAM beyond the first dam 1DAM. Even though the cover layer 118 is formed beyond the first dam 1DAM, the second dam 2DAM suppresses the cover layer 118 from extending to the bending area BA.

The polarization layer 293 is disposed on the cover layer 118 by means of the first adhesive layer 291. A cover member 200 is disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the example implementations of the present disclosure are not limited thereto.

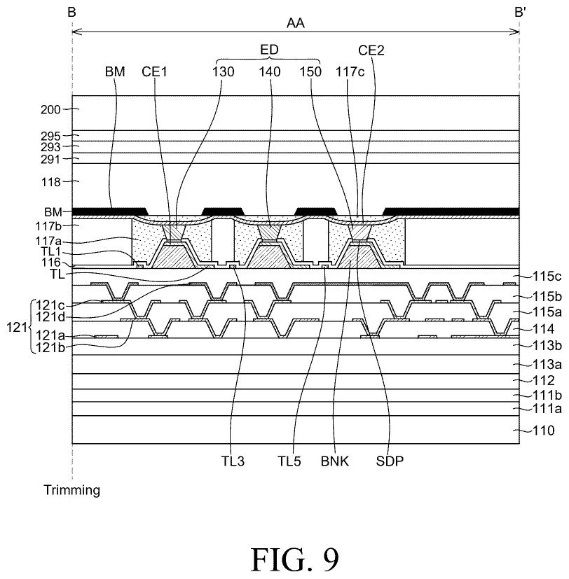

FIG. 9 is a cross-sectional view taken along B-B′ of FIG. 4. The display device 1000 according to the present disclosure is cut in accordance with the size of the display device 1000, in a panel state formed from the substrate 110 to the cover layer 118.

FIG. 4 illustrates pixels PXL formed at an end portion of the display device 1000 and B-B′ of FIG. 4 is a trimming line which cuts a panel formed from the substrate 110 to the cover layer 118.

The first micro LED 130, the second micro LED 140, and the third micro LED 150 are disposed on the bank BNK and the second electrode CE is commonly connected to the first micro LED 130, the second micro LED 140, and the third micro LED 150.

Insulating layers formed of an organic material on the substrate 110 on the trimming line are cut after completing all the deposition processes so that the end surface is not inclined.

A panel formed from the substrate 110 to the cover layer 118 is cut so that ends of the substrate 110 and the passivation layer 116 and the insulating layers (such as first buffer layer 111a, second buffer layer 111b, adhesive layer 112, first protection layer 113a, second protection layer 113b, third protection layer 114, first insulating layer 115a, second insulating layer 115b, and third insulating layer 115c) disposed between the substrate 110 and the passivation layer 116 may match. However, the example implementations of the present disclosure are not limited thereto.

Further, ends of the substrate 110 and a second optical layer 117b, the black matrix BM, and the cover layer 118 may match, but the example implementations of the present disclosure are not limited thereto.

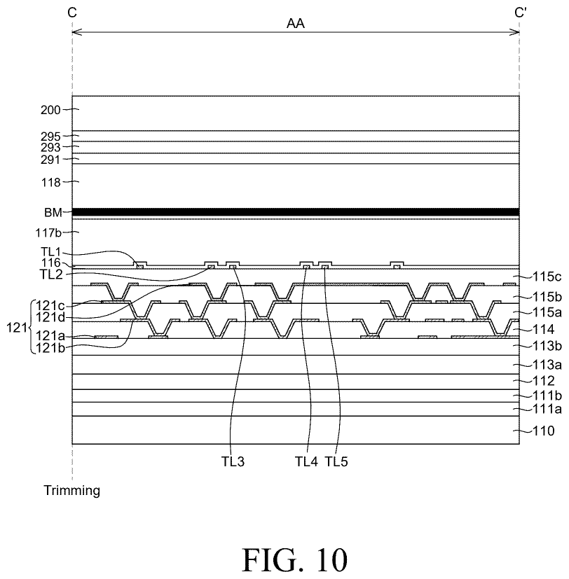

FIG. 10 is a cross-sectional view taken along C-C′ of FIG. 4. C-C′ of FIG. 4 is an end portion of the display device 1000 and is an area in which the pixel PXL is not disposed. C-C′ of FIG. 4 may be a trimming line which cuts a panel formed from the substrate 110 to the cover layer 118. Insulating layers formed of an organic material on the substrate 110 on the trimming line are cut after completing all the deposition processes so that the end surface is not inclined. FIG. 10 is an area in which the pixel PXL is not disposed and the second electrode CE is not disposed thereabove.

A panel formed from the substrate 110 to the cover layer 118 is cut so that ends of the substrate 110 and the passivation layer 116 and the insulating layers (such first buffer layer 111a, second buffer layer 111b, adhesive layer 112, first protection layer 113a, second protection layer 113b, third protection layer 114, first insulating layer 115a, second insulating layer 115b, and third insulating layer 115c) disposed between the substrate 110 and the passivation layer 116 may match. However, the example implementations of the present disclosure are not limited thereto.

Further, ends of the substrate 110 and ends of a second optical layer 117b, the black matrix BM, and the cover layer 118 may match, but the example implementations of the present disclosure are not limited thereto.

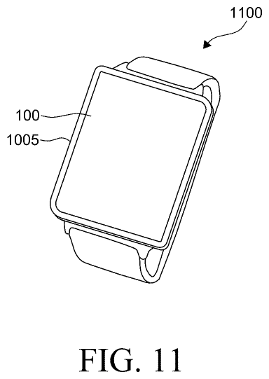

FIG. 11 is an example of a device to which a display device according to example implementations of the present disclosure is applied and referring to FIG. 11, an electronic device is included in a wearable device 1100. The display device 1000 according to the example implementations of the present disclosure may be applied to a mobile device, a notebook, a monitor, or a TV, but the example implementations of the present disclosure are not limited thereto.

Such an electronic device includes a case unit 1005, a display panel 100, and a display device 1000.

The example implementations of the present disclosure can also be described as follows:

According to an implementation of the present disclosure, a display device includes a substrate including an active area, a non-active area disposed on at least one side surface of the active area, and a bending area disposed between the active area and the non-active area, a plurality of insulating layers disposed on the substrate, a bank disposed on the plurality of insulating layers, at least one micro LED disposed on the bank, an optical layer disposed on the plurality of insulating layers, a dam area between the active area and the bending area and a first dam disposed in the dam area, wherein the first dam includes a first dam layer which is formed of the same material as the bank.

The first dam may further include a second dam layer which is disposed on the first dam layer in the dam area and is formed of the same material as the optical layer.

The display device may further include a black matrix disposed on the optical layer.

The black matrix may extend to the dam area and may be at least partially disposed on the first dam layer.

The display device may further include a protection layer disposed on the black matrix, the protection layer may be at least partially disposed on the first dam.

As an insulating layer may be disposed in the bending area, at least one of the plurality of insulating layers may be disposed in the active area of the substrate.

The display device may further include a second dam between the first dam and the bending area.

The second dam may include a third dam layer which is formed of the same material as the bank.

The second dam may further include a fourth dam layer which is formed of the same material as the optical layer on the third dam layer.

The display device may further include a passivation layer disposed on the plurality of insulating layers and the bank, the passivation layer may extend to the dam area.

According to another implementation of the present disclosure, a display device includes a substrate including an active area, a non-active area disposed on at least one side surface of the active area, and a bending area between the active area and the non-active area, a plurality of insulating layers disposed on the substrate in the active area, a bank disposed on the plurality of insulating layers, at least one micro LED disposed on the bank, an optical layer disposed on the plurality of insulating layers, a black matrix disposed on the optical layer and at least one dam disposed in a dam area between the active area and the bending area, wherein at least one dam includes a first dam layer which is formed of the same material as the bank.

At least one dam may further include a second dam layer which is disposed on the first dam layer and is formed of the same material as the optical layer.

The black matrix may extend to the dam area and may be at least partially disposed on the first dam layer.

The display device may further include a cover layer disposed on the black matrix, the cover layer is not disposed on a side surface closer to the bending area, between side surfaces of at least one dam.

At least one end of the substrate may match an end of the black matrix.

The bank may be disposed on the plurality of insulating layers and at least one micro LED may be disposed on the bank.

As an insulating layer may be disposed in the bending area, at least one of the plurality of insulating layers may be disposed in the active area of the substrate.

The display device may further include a driving circuit disposed on the substrate and the plurality of insulating layers, the driving circuit is electrically connected to the at least one micro LED.

The at least one micro LED may include an anode electrode disposed below the at least one micro LED and a cathode electrode disposed above the at least one micro LED.

Although the example implementations of the present disclosure have been described in detail with reference to the accompanying drawings, the present disclosure is not limited thereto and may be embodied in many different forms without departing from the technical concept of the present disclosure. Therefore, the example implementations of the present disclosure are provided for illustrative purposes only but not intended to limit the technical concept of the present disclosure. The scope of the technical concept of the present disclosure is not limited thereto. Therefore, it should be understood that the above-described example implementations are illustrative in all aspects and do not limit the present disclosure. All the technical concepts in the equivalent scope of the present disclosure should be construed as falling within the scope of the present disclosure.

What is claimed is:

1. A display device, comprising:
a substrate including an active area, a non-active area disposed on at least one side surface of the active area, and a bending area disposed between the active area and the non-active area;
a plurality of insulating layers disposed on the substrate;
a bank disposed on the plurality of insulating layers;
at least one micro light emitting diode (LED) disposed on the bank;
an optical layer disposed on the plurality of insulating layers;
a dam area between the active area and the bending area; and
a first dam disposed in the dam area,
wherein the first dam includes a first dam layer which is formed of a same material as the bank.

2. The display device according to claim 1, wherein the first dam further includes a second dam layer which is disposed on the first dam layer in the dam area, and the second dam layer is formed of a same material as the optical layer.

3. The display device according to claim 1, further comprising:
a black matrix disposed on the optical layer.

4. The display device according to claim 3, wherein the black matrix extends to the dam area, and the black matrix is at least partially disposed on the first dam layer.

5. The display device according to claim 3, further comprising:
a protection layer disposed on the black matrix,
wherein the protection layer is at least partially disposed on the first dam.

6. The display device according to claim 1, wherein as an insulating layer disposed in the bending area, at least one of the plurality of insulating layers is disposed in the active area of the substrate.

7. The display device according to claim 1, further comprising:
a second dam between the first dam and the bending area.

8. The display device according to claim 7, wherein the second dam includes a third dam layer which is formed of the same material as the bank.

9. The display device according to claim 8, wherein the second dam further includes a fourth dam layer on the third dam layer, and the fourth dam layer is formed of the same material as the optical layer.

10. The display device according to claim 8, further comprising:
a passivation layer disposed on the plurality of insulating layers and the bank,
wherein the passivation layer extends to the dam area.

11. A display device, comprising:
a substrate including an active area, a non-active area disposed on at least one side surface of the active area, and a bending area between the active area and the non-active area;
a plurality of insulating layers disposed on the substrate in the active area;
a bank disposed on the plurality of insulating layers;
at least one micro light emitting diode (LED) disposed on the bank;
an optical layer disposed on the plurality of insulating layers;
a black matrix disposed on the optical layer; and
at least one dam disposed in a dam area between the active area and the bending area,
wherein the at least one dam includes a first dam layer which is formed of a same material as the bank.

12. The display device according to claim 11, wherein at least one dam further includes a second dam layer which is disposed on the first dam layer, and the second dam layer is formed of a same material as the optical layer.

13. The display device according to claim 11, wherein the black matrix extends to the dam area, and the black matrix is at least partially disposed on the first dam layer.

14. The display device according to claim 11, further comprising:
a cover layer disposed on the black matrix,
wherein the cover layer is not disposed on a side surface closer to the bending area, and the cover layer is disposed between side surfaces of at least one dam.

15. The display device according to claim 11, wherein at least one end of the substrate matches an end of the black matrix.

16. The display device according to claim 11, wherein the bank is disposed on the plurality of insulating layers and the at least one micro LED is disposed on the bank.

17. The display device according to claim 11, wherein as an insulating layer disposed in the bending area, at least one of the plurality of insulating layers is disposed in the active area of the substrate.

18. The display device according to claim 11, further comprising:
a driving circuit disposed on the substrate and the plurality of insulating layers,
wherein the driving circuit is electrically connected to the at least one micro LED.

19. The display device according to claim 18, wherein the at least one micro LED includes an anode electrode disposed below the at least one micro LED and a cathode electrode disposed above the at least one micro LED.
